(19) United States
(12) Patent Application Publication
(10) Pub. No.: US 2007/0284599 A1
(43) Pub. Date: Dec. 13, 2007

(54) Process for producing group III nitride semiconductor stacked structure

(75) Inventor: Hiromitsu Sakai, Ichihara-shi (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Minato-ku (JP)

(21) Appl. No.: 11/808,023

(22) Filed: Jun. 6, 2007

(30) Foreign Application Priority Data
Jun. 8, 2006 (JP) 2006-159470

(51) Int. Cl. H01L 33/00; H01L 21/00

(52) U.S. Cl. 257/94; 438/46; 257/E33.023

(57) ABSTRACT

An object of the present invention is to provide a method of producing a Group III nitride semiconductor stacked structure which is useful for the production of reliable and excellent Group III nitride semiconductor light emitting devices having low forward voltage and small temporal changes in the forward voltage without lowering the light emitting output by keeping an excellent crystallinity of the light emitting layer and improving the crystallinity of the p-type layer.

In the inventive method of producing a Group III nitride semiconductor stacked structure, the stacked structure has an n-type underlying layer, an active layer, a p-type cladding layer and a p-type contact layer, each comprising a Group III nitride semiconductor, in this order on a substrate, wherein the p-type contact layer is grown at two or more temperature ranges of substrate temperature, and the temperature range at the later growth is higher than that at the first growth.

### FIELD OF THE INVENTION

The present invention relates to a method for producing a light emitting device that emits high-output light in the blue, green or ultraviolet band.

### BACKGROUND OF THE INVENTION

In recent years, Group III nitride semiconductor materials are drawing attention as semiconductor materials for light emitting devices which emit short-wavelength light. Generally, Group III nitride semiconductors are stacked on a substrate composed of various oxide crystals, such as sapphire single crystals, silicon carbide single crystals, or single crystals of Group III-V compound semiconductors by a metal organic chemical vapor deposition (MOCVD) method, a molecular beam epitaxy (MBE) method, a hydride vapor phase epitaxy (HVPE) method or the like.

The current method of growing crystals most widely used on an industrial level uses as the substrate, sapphire, SiC, GaN, AlN, etc., on which crystals are formed using a metal organic chemical vapor deposition (MOCVD) method, wherein using a Group III organic metal compound and a Group V material gas, an n-type layer, a light emitting layer and a p-type layer are grown in the region of about 700-1200° C. in a reaction tube with the above substrate. After each semiconductor layer has grown, a negative electrode is formed on the substrate or the n-type layer and a positive electrode is formed on the p-type layer thereby to obtain a light emitting device.

For example, in order to produce highly reliable devices, Japanese Unexamined Patent Publication (Kokai) No. 2004-72044 defines the film thicknesses for the n-type layer, the p-type layer, and the substrate temperature. In the LED described in this publication, an n-type GaN semiconductor layer having a thickness in the range of 0.4-5 μm, an active layer, and a p-type GaN semiconductor layer having a thickness in the range of 0.05-1 μm are formed in this order on the substrate, and the n-type GaN semiconductor layer grows at a substrate temperature of 1100° C. or higher and the p-type GaN semiconductor layer grows at a substrate temperature of less than 1100° C.

Also in Japanese Patent No. 3654738, an n-type layer comprising a Group III nitride semiconductor is formed at a substrate temperature of 1150° C. and a light emitting layer is formed at 850° C. on the substrate, and then a p-type cladding layer is formed at 1100° C., followed by a second contact layer at 850° C. and a first contact layer is formed at the same temperature of 850° C. Thus, the substrate temperature of the contact layer is lower than that of the cladding layer for growth. However, when the present inventors fabricated a Group III nitride semiconductor light emitting device in a conventional method, the p-type layer proved to have poor crystallinity, and therefore the light emitting output of the device was weak with the operating voltage at 20 mA becoming higher, and the operating voltage varied due to aging, and there was also a problem in yield.

For evaluating the crystallinity of a p-type layer, there is a method that employs, for example, a transmission electron microscope (TEM) observation. However, this has drawbacks in that it requires a highly skilled technique, takes a lot of time for evaluation, and the area to be observed is narrow. On the other hand, X-ray diffraction analysis, which is easier to perform and has a wider area to be observed, is widely used as an alternative to TEM. It is reported in, for example, Jpn. J. Appl. Phys., Vol. 42 (2003) L1-L3, that in X-ray diffraction, the analysis of an X-ray rocking curve half-width (XRC FWHM) of the (10-10) plane is useful. In XRC measurement of the (10-10) plane, X-rays are incident at an angle close to the growing plane, and thus yields information on crystallinity in the vicinity of the surface. Thus, it is possible to determine the crystallinity of a p-type layer.

However, there are only reports on gallium nitride single films, and no reports on stacked layers of a light emitting diode structure, and thus the evaluation of p-type layer crystallinity in an LED structure is not known. In brief, no specific investigations have been conducted so far in order to enhance the crystallinity of a p-type layer by a method of fabricating a p-type layer, and to thereby improve device reliability.

Also, it is generally known that when operating voltage (for example, a forward voltage at 20 mA) is high, or when values change greatly with time due to aging, light emitting output may decrease or electrostatic breakdown voltage may decrease, which leads to decreased reliability. Therefore, it is necessary to suppress such enhancement in the operating voltage and minimize changes with time.

Furthermore, it is also generally known that even when voltage in a low electric current region (for example, forward voltage at 10 μA) is low, or values change greatly with time, light emitting output may decrease or electrostatic breakdown voltage may decrease, which leads to decreased reliability.

### SUMMARY OF THE INVENTION

The present invention was made taking into account the above problems, and it is an object of the present invention to provide a method of producing a Group III nitride semiconductor stacked structure, which is useful for the production of reliable and excellent Group III nitride semiconductor light emitting devices having a low forward voltage (driving voltage) at 20 mA and small temporal changes in the forward voltage at 20 mA without lowering the light emitting output by keeping an excellent crystallinity of the light emitting layer and improving the crystallinity of the p-type layer.

The present invention provides the following inventions:

(1) A method of producing a Group III nitride semiconductor stacked structure having an n-type underlying layer, an active layer, a p-type cladding layer and a p-type contact layer, each comprising a Group III nitride semiconductor, in this order on a substrate, wherein the p-type contact layer is grown at two or more times the temperature range of the substrate temperature, and the temperature range at later growth is higher than that at first growth.

(2) A method of producing a Group III nitride semiconductor stacked structure according to the above item 1 wherein the active layer comprises In.

(3) A method of producing a Group III nitride semiconductor stacked structure according to above item 1 or 2 wherein the p-type cladding layer comprises aluminum gallium nitride (AlₓGa₁₋ₓN: 0≦x≦0.5).

(4) A method of producing a Group III nitride semiconductor stacked structure according to any one of above items 1 to 3 wherein the p-type contact layer comprises aluminum gallium nitride (AlₓGa₁₋ₓN: 0≦x≦0.1).

(5) A method of producing a Group III nitride semiconductor stacked structure according to any one of above items 1 to 4 wherein when the substrate temperature during the growth of the n-type underlying layer is set at TOC, the substrate temperature during the growth of the p-type cladding layer is set at TOC, the substrate temperature in first stage during the growth of the p-type contact layer is set at T1° C., and the substrate temperature in the second stage during the growth of the p-type contact layer is set at T2° C., T, T0, T1 and T2 satisfy the following formula:

T−70<T1<T

T−30<T2<T+30

T1<T2

T0<T, T2

(6) A Group III nitride semiconductor stacked structure produced by any one of above items 1 to 5.

(7) A Group III nitride semiconductor stacked structure having an n-type underlying layer, an active layer, a p-type cladding layer and a p-type contact layer, each comprising a Group III nitride semiconductor, in this order on a substrate wherein the half-width of an X-ray rocking curve (XRC FWHM) of the (10-10) plane of the p-type contact layer is 400 arcsec or smaller.

(8) A Group III nitride semiconductor stacked structure according to above item 6 or 7 wherein the thickness of the p-type contact layer is 50-300 nm.

(9) A Group III nitride semiconductor stacked structure according to above item 8 wherein the thickness of the p-type contact layer in the first stage is 10 nm or greater.

(10) A Group III nitride semiconductor stacked structure according to above item 8 or 9 wherein the thickness of the p-type contact layer in the second stage is 30 nm or greater.

(11) A Group III nitride semiconductor stacked structure according to any one of above items 6 to 10 wherein the thickness of the p-type cladding layer is 10-100 nm.

(12) A light emitting device comprising a Group III nitride semiconductor stacked structure according to any one of above items 6 to 11.

(13) A light emitting device according to above item 12 wherein the light emitting wavelength is 420 nm or smaller.

(14) A lamp comprising a light emitting device according to above item 12 or 13.

(15) An electronic device in which the lamp according to above item 14 has been integrated.

(16) A mechanical instrument in which the electronic device according to above item 15 has been integrated.

According to the method of producing a Group III nitride semiconductor stacked structure of the present invention, a Group III nitride semiconductor stacked structure having good crystallinity of the p-type layer can be produced while keeping good crystallinity of the active layer. Thus, using a Group III nitride semiconductor stacked structure obtained by the present invention, a highly reliable Group III nitride semiconductor light emitting device can be produced which has a high light emitting output and a low forward voltage at 20 mA, and further small temporal changes in the forward voltage at 20 mA and 10 μA, and therefore a lower incidence of a decreased light emitting output and a decreased electrostatic breakdown voltage.

### BRIEF DESCRIPTION OF THE DRAWINGS

FIG. 1 is a schematic sectional view of an LED comprising a Group III nitride semiconductor stacked structure of the present invention.

FIG. 2 is a schematic sectional view of a Group III nitride semiconductor stacked structure of the present invention fabricated in Example 1.

FIG. 3 is a schematic plan view of an electrode of an LED fabricated in Example 1.

FIG. 4 is a schematic diagram showing a method of measuring the (10-10) plane X-ray rocking curve of a Group III nitride semiconductor.

### DETAILED DESCRIPTION OF THE INVENTION

In accordance with the present invention, there can be used, as the substrate, known substrate materials without limitation, for example oxide monocrystals, such as sapphire monocrystals (Al₂O₃: A plane, C plane, M plane, R plane), spinel monocrystals (MgAl₂O₄), ZnO monocrystals, LiAlO₂ monocrystals, LiGaO₂ monocrystals and MgO monocrystals, Si monocrystals, SiC monocrystals, GaAs monocrystals, AlN monocrystals, GaN monocrystals, and boride monocrystals such as ZrB₂, and the like. Herein, the plane orientation of the substrate is not specifically limited. The crystal plane of the substrate may be inclined to a specific crystal plane or not inclined.

A Group III nitride semiconductor that constitutes a Group III nitride semiconductor stacked structure produced by the method of the present invention contains binary mixed crystals of InN, AlN etc. in addition to GaN, ternary mixed crystals of GaInN, AlGaN etc., and quaternary mixed crystals of AlGaInN etc. In the present invention, there can also be used, as the Group III nitride semiconductor, ternary mixed crystals, such as GaPN, GaNAs etc. that contain Group V elements other than nitrogen, quaternary mixed crystals such as GaInPN, GaInAsN, AlGaPN and AlGaAsN etc., containing In and Al in addition to the above, quinqupartite mixed crystals, such as AlGaInPN, AlGaInAsN etc., containing both In and Al and AlGaPAsN, GaInPAsN etc., containing both P and As, and sexpartite mixed crystals, such as AlGaInPAsN containing all elements.

In the present invention, the Group III nitride semiconductors containing only N as a Group V, for example, binary mixed crystals of GaN, InN, AlN etc., ternary mixed crystals of GaInN, AlGaN etc., and quaternary mixed crystals of AlGaInN etc., which are relatively easy to prepare and less hazardous among the above, can be suitably used. When expressed in a general formula AlₓGa₁₋ₓIn_{y}N (0≦x+y≦1), x is preferably in the range of 0-0.5 and y in the range of 0-0.4.

A Group III nitride semiconductor for use in the present invention can contain other Group III elements in addition to Al, Ga and In, and can contain, as needed, such elements as Ge, Si, Mg, Ca, Zn, Be, P, As and B. Furthermore, in addition to elements that were intentionally added, impurities may be inherently contained depending on the growing conditions, as well as trace amounts of impurities contained in the material and the material for the reaction tube.

Also, a p-type dopant for use in the present invention includes Mg, Ca, Zn, Cd, Hg etc., that have been reported or predicted to be doped with Group III nitride semiconductors so as to exhibit p-type conductivity. Among them, Mg having a high activation rate by heat treatment is specifically preferred as a p-type dopant. The amount of the dopant is preferably 1×10¹⁸−1×10²¹ cm⁻³. When it is less than 1×10¹⁸ cm⁻³, light emitting output may decrease. When it is greater than 1×10²¹ cm⁻³, crystallinity may be aggravated and is not preferred. More preferably it is 1×10¹⁹−5×10²⁰ cm⁻³.

Methods of growing a Group III nitride semiconductor for use in the present invention are not specifically limited, and any methods known to grow Group III nitride semiconductors such as a metal organic chemical vapor deposition (MOCVD) method, a hydride vapor phase epitaxy (HVPE) method and a molecular beam epitaxy (MBE) method can be used. A preferred growth method is the MOCVD method from the viewpoint of controllability of film thickness and capability of mass production.

In the MOCVD method, a hydrogen gas (H₂) or a nitrogen gas (N₂) as the carrier gas, trimethyl gallium (TMGa) or triethyl gallium (TEGa) as the Ga source that is a Group III source, trimethyl aluminum (TMAl) or triethyl aluminum (TEAl) as the Al source that is a Group III source, trimethyl indium (TMIn) or triethyl indium (TEIn) as the In source that is a Group III source, and ammonia (NH₃) or hydrazine (N₂H₄) as the nitrogen source are used, respectively. As the p-type dopant, biscyclopentadienyl magnesium (Cp₂Mg) or bisethylcyclopentadienyl magnesium ((EtCp)₂Mg) as the Mg source, and zinc dimethyl (Zn(CH₃)₂) as the Zn source are used, respectively.

The method of producing a Group III nitride semiconductor stacked structure of the present invention may be used for the production of various semiconductor devices. For example, in addition to semiconductor light emitting devices, such as light emitting diodes and laser diodes, it can be used for the production of any semiconductor devices if they are semiconductor devices that require a Group III nitride semiconductor stacked structure such as light-receiving elements. Among the various semiconductor devices, it can be used most suitably for the production of semiconductor light emitting devices that require the formation of a pn junction and the formation of a positive electrode with a favorable characteristics.

By way of example, the present invention will be described with reference to light emitting diodes (LED).

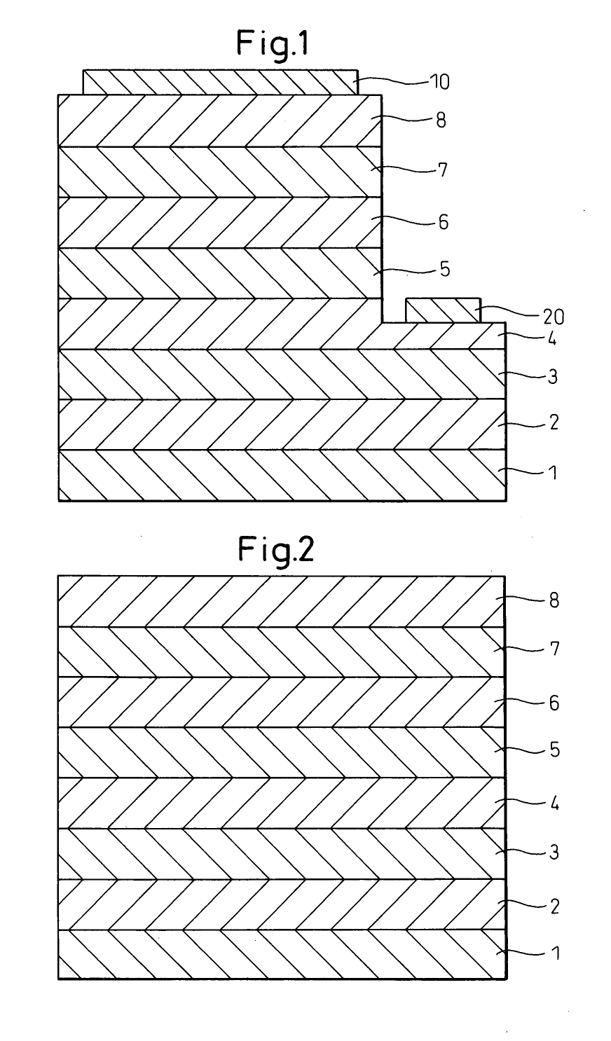

An LED structure comprising a Group III nitride semiconductor stacked structure of the present invention may take a form, as shown in FIG. 1, in which on a substrate (1), via a buffer layer (2) as needed, a n-type underlying layer (3) comprising an undoped n-type GaN layer, a n-type contact layer (4) comprising a Si-doped n-type GaN, a n-type cladding layer (5) comprising a Si-doped n-type GaInN, a light emitting layer (6) of a multiple quantum well structure in which a barrier layer comprising Si-doped GaN and a well layer comprising undoped GaInN have been alternately stacked, a p-type cladding layer (7) comprising a Mg-doped p-type AlGaN, and a p-type contact layer (8) comprising a Mg-doped p-type AlGaN have been sequentially stacked. An additional layer may be added in addition to them, or some of these layers may be omitted, or the composition or impurities of each layer may be changed. A negative electrode (20) may be provided adjacent to the n-type contact layer (4), and a positive electrode (10) may be provided adjacent to the p-type contact layer (8).

In accordance with the present invention, an LED structure comprising a Group III nitride semiconductor is formed by an MOCVD method. As materials for the MOCVD method, Group III organic metal materials, such as trimethyl gallium (TMGa), trimethyl aluminum (TMAl) and trimethyl indium (TMIn) and a nitrogen material, such as ammonia are used, and are subjected to thermal decomposition so as to deposit a Group III nitride semiconductor layer on the buffer layer. In order to add impurities, silane (SiH₄) is used when silicon is to be doped, an organic metal germanium compound is used when germanium is to be doped, or biscyclopentadienyl magnesium (Cp₂Mg) etc., is used when magnesium is to be doped. The conditions of the substrate temperature and a carrier gas may be experimentally determined as appropriate.

Other than a GaN substrate, in order to stack a gallium nitride compound semiconductor on the above substrate that does not lattice match, in principle with a gallium nitride compound, a low temperature buffer method disclosed in the Japanese Patent No. 3026087 and Japanese Unexamined Patent Publication (Kokai) No. 4-297023 or a Seeding Process (SP) method, a lattice mismatch crystal epitaxial growth technique, disclosed in Japanese Unexamined Patent Publication (Kokai) No. 2003-24330 may be used. In particular, the SP method capable of forming AlN crystal films at high temperatures that permit the formation of GaN crystals is an excellent lattice mismatch crystal epitaxial growth technique in terms of enhanced productivity.

In accordance with the present invention, the buffer layer 2 comprises AlN, for example, and is preferably formed by a SP method. The film thickness of the buffer layer 2 is preferably 0.001-1 μm, more preferably 0.005-0.5 μm, and most preferably 0.01-0.2 μm. When the film thickness is within the range described above, the crystal morphology of the nitride semiconductor of the underlying layer 3 and after that are thereupon grown becomes desirable and crystallinity can be improved.

The buffer layer 2 may be produced by a MOCVD method. The substrate temperature is preferably in the range of 400-1200° C., and more preferably in the range of 900-1200° C. When the substrate temperature is within the range described above, AlN becomes monocyrstals, and thus the crystallinity of nitride semiconductors grown thereon becomes desirable.

When AlN monocrystals are used as the substrate, the substrate is assumed to serve as the buffer layer 2 as well.

The n-type underlying layer 3 may comprise, for example, GaN, and may be doped with a n-type impurity such as Si, if it is within the range of 1×10¹⁷−1×10¹⁹/cm³. However, undoped ones are preferred in order to maintain excellent crystallinity. For example, n-type impurities include, but not limited to, Si, Ge, Sn et., and they are preferably Si and Ge.

Substrate temperature for growing the n-type underlying layer 3 is preferably 800-1200° C., and, more preferably, is adjusted to a range of 1000-1200° C. If it decreases below 1000° C., pits may occur on the surface thus deteriorating crystallinity. On the other hand, if it is higher than 1200° C., the sublimation of the GaN layer renders the surface rugged, and thus is not desirable. Pressure in the MOCVD-growing furnace is adjusted to be 15−40 kPa.

Preferably the film thickness of the n-type underlying layer 3 is, but not limited to, 4-20 μm, and more preferably 6-15 μm. When the film thickness is within this range, excellent crystallinity may be maintained and thus is desirable. On the other hand, when the film thickness is smaller than this range, crystallinity may deteriorate resulting in reduced light emitting output, and thus is not desirable. On the other hand, when it is thicker than this range, the backward bending of the wafer becomes greater, causing enhanced distribution of light emitting wavelength and reduced yield during device fabrication.

In accordance with the present invention, the better the crystallinity of the n-type underlying layer 3 is, the greater the effect of the present invention is. As an index of crystallinity, the XRC FWHM of the (10-10) plane is 300 arcsec or less, and the dislocation density is 10⁸ cm⁻² or greater and less than 10⁹ cm⁻².

As the n-type contact layer 4, a n-type dopant-doped layer, for example a Si-doped Al_{b}Gal_{b}N layer (0≦b≦1, preferably 0≦b≦0.5, more preferably 0≦b≦0.1) is preferred. The amount of the n-type dopant is preferably 5×10¹⁷-5×10¹⁹/cm³, preferably 1×10¹⁸−1×10¹⁹/cm³, from the viewpoint of maintaining excellent ohmic contact, suppressing the occurrence of cracks, and maintaining excellent crystallinity.

When an n-type impurity is doped in the underlying layer 3, the underlying layer 3 may also serve as the n-type contact layer 4. However, it is preferred that the underlying layer 3 is low-doped and the n contact layer 4 is high-doped.

The substrate temperature for growing the n-type contact 4 is preferably 800-1200° C. as for the underlying layer 3, and more preferably, is adjusted to a range of 1000-1200° C. The substrate temperature of the n-type contact layer may be the same as the underlying layer or the substrate temperature may be raised in order to enhance crystallinity. The film thickness of the n-type contact layer 4, combined with the underlying layer 3, is preferably within the range of the above underlying layer.

It is preferred to provide an n-type cladding layer 5 in between the n-type contact layer 4 and the light emitting layer 6. Because it can offset aggravated flatness that occurred on the uppermost surface of the n-type contact layer. The n-type cladding layer may be formed of AlGaN, GaN, GaInN etc. These structures may be heterojunctions or multiply stacked superlattice structures. When GaInN is used, it is naturally preferred to be larger than the band gap of GaInN of the light emitting layer. The n-type cladding layer to be under the above condition is preferred in terms of containment of carriers in the light emitting layer. The film thickness of the n-type cladding layer is preferably, but not limited to, 0.005-0.5 μm, and more preferably 0.005-0.1 μm. The n-type dope concentration of the n-type cladding layer is preferably 1×10¹⁷−1×10²⁰/cm³, and more preferably 1×10¹⁸−1×10¹⁹/cm³. The dope concentration within this range is desirable in terms of maintaining excellent crystallinity and of reduced operating voltage of the device.

As the light emitting layer 6, a Group III nitride semiconductor of Ga₁₋ₛInₛN (0≦s≦0.4) is preferred. Preferably the film thickness of the light emitting layer is, but not limited to, about a thickness in which quantum effect can be obtained, and is preferably 1-10 nm, and more preferably 2-6 nm. The film thickness in the above range is preferred in terms of light emitting output. In composition is adjusted to an intended light emitting wavelength.

Preferably the substrate temperature for growing a light emitting layer is generally 600-900° C., and more preferably 700-800° C. When the temperature is low, the crystallinity of the light emitting layer deteriorates which is not desirable. Higher substrate temperature leads to good crystallinity. However, when it is too high, the efficiency of In being incorporated into the solid phase becomes decreased, and thus the desired light emitting wavelength cannot be obtained. With increases in temperature, the distribution of the light emitting wavelength may be expanded and the controllability of wavelength becomes difficult, and thus there is the upper limit to the optimum substrate temperature.

The light emitting layer, in addition to the above single quantum well (SQW) structure, may take a multiple quantum well (MQW) structure comprising the above Ga₁₋ₛInₛN as the well layer and a Al_{c}Ga_{1-c}N (0≦c≦0.2, b>c) barrier layer having a band gap energy greater than the well layer. The well layer and/or the barrier layer may be doped with impurities.

The p-type cladding layer 7 is not specifically limited as long as it has a band gap energy greater than that of the light emitting layer and permits the containment of carriers into the light emitting layer, however, there can preferably be one that has a composition of Al_{d}Ga_{1-d}N (0≦d≦0.5, preferably 0.05≦d≦0.2). The p-type cladding layer comprising such AlGaN is preferred in terms of containment of carriers into the light emitting layer. The film thickness of the p-type cladding layer is preferably 10-200 nm, and more preferably 10-100 nm. When it is thinner than this range, the efficiency of containing carriers may decrease, while when it is thicker, the crystallinity of the p-type cladding layer deteriorates, and thus the crystallinity of the p-type contact layer 8 stacked thereon deteriorates, which is not desirable.

The p-type dope concentration of the p-type cladding layer 7 is preferably 1×10¹⁸−1×10²¹/cm³, and more preferably 1×10¹⁹-5×10²⁰/cm³. When the dope concentration is within the above range, a good p-type cladding layer can be obtained without reducing crystallinity.

The substrate temperature for growing a p-type cladding layer is preferably 900-1100° C., and more preferably adjusted to be in the range of 1000-1100° C. When the substrate temperature is low, the crystallinity of the p-type cladding layer deteriorates, which leads to a reduction of light emitting output and an increase in operating voltage. On the other hand, when the substrate temperature is high, the light emitting layer is thermally damaged, which leads to deteriorated crystallinity of the light emitting layer and reduced light emitting output. Preferably the upper limit is lower than the temperature during the growth of a n-type underlying layer and lower than the substrate temperature during the second step of growth of the p-type contact layer described below.

The p-type contact layer 8 is preferably a Group III nitride semiconductor layer comprising AlₑGa₁₋ₑN (0≦e≦0.2, preferably 0≦e≦0.1, more preferably 0≦e≦0.05). The Al composition within the above range is preferred in terms of maintenance of good crystallinity and good ohmic contact. The p-type dope contained at a concentration of 1×10¹⁸−1×10²¹/cm³, preferably 5×10¹⁹-5×10²⁰/cm³, is preferred in terms of maintenance of good ohmic contact, prevention of cracking, and maintenance of good crystallinity. As p-type impurities, there can be preferably mentioned, but not limited to, Mg.

Preferably the substrate temperature during the growth of the p-type contact layer comprises two or more temperature ranges, and preferably the temperature range during a later growth is higher than the temperature range during the first growth. In the case wherein the substrate temperature is low and constant, the XRC FWHM of the (10-10) plane becomes enhanced and the crystallinity of the p-type contact layer deteriorates. It may lead to reduced light emitting output and enhanced operational voltage of the light emitting device, and voltage variation easily occurs due to aging, which is not desirable. On the other hand, in the case wherein the substrate temperature is high and constant, the light emitting layer is thermally damaged and the light emitting output decreases. When the substrate temperature during the growth of the p-type layer is raised to the same temperature as the n-type layer, the crystallinity of the p-type layer becomes better. However, raising the same temperature as that of the n-type layer during the initial growth will deteriorate the crystallinity of the light emitting layer, and thus should be avoided.

The upper limit of growth temperature at the second stage is decided by the In composition in the well layer. Thus, when the In composition is high, the light emitting layer tends to be thermally deteriorated. Thus, the temperature should be set at lower levels compared to when the In composition is low. On the other hand, when the ratio of In composition in the light emitting layer is low, it is refractory to thermal deterioration, and thus the temperature can be set at higher levels.

With regard to increases in substrate temperature during the growth of the p-type contact layer, low temperature at the first stage has a role of protecting the light emitting layer, and high temperature at the second stage has a role of enhancing the crystallinity of the p-type contact layer. If similar effects are to be obtained, the substrate temperature during the growth of the p-type contact layer may be divided into three or more temperature ranges.

During transition from the first stage to the second stage, the substrate temperature may be raised while allowing the p-type contact layer to grow. Also, the substrate temperature may be raised while suspending the feeding of the Group III material and continuing the feeding of the Group V material. In this case, however, raising the temperature for 30 minutes or longer may inflict thermal damage on the light emitting layer, which is not desirable.

When the substrate temperatures during the respective growth of the n-type underlying layer, the p-type cladding layer, the p-type contact layer during the first stage and the p-type contact layer during the second stage are set as T° C., T0° C., T1° C. and T2 ° C., they preferably satisfy the following relationship:

T−70<T1<T

T−30<T2<T+30

T1<T2

T0<T, T2

When the film thickness at the first stage is set at t1 and that at the second stage at t2, the film thickness t1 at the first stage is preferably a film thickness that can protect the light emitting layer and preferably t1≧10 nm. The film thickness t2 at the second stage is preferably t2≧30 nm from the viewpoint of enhancing the crystallinity of the p-type contact layer. The entire film thickness of the p-type contact layer is preferably, but not limited to, 50-500 nm, and more preferably 50-300 nm. The film thickness within this range is desirable in terms of light emitting output.

The effect of the present invention is greater on light emitting devices with a short wavelength of 420 nm or less. Since in a 420 nm LED, the In composition in the light emitting layer is low compared to a general 460 nm blue LED, the overflow of carriers tends to occur. Thus, in order to enhance the effect of containing carriers, it is necessary to modify the structure, by for example, raising the Al composition in the p-type cladding layer or increasing the film thickness of the p-type cladding layer. As a result of investigation by the present inventors, it was found that crystallinity may be deteriorated when the growth of a p-type layer is attempted under the condition. By using the two-step growth method of the p-type contact layer of the present invention, the growth temperature of the p-type layer can be raised and a good p-type layer can be obtained without deteriorating the crystallinity of the light emitting layer.

In accordance with the present invention, the p-type layer is preferably formed under the condition that the half-width of the X-ray rocking curve (XRC FWHM) of the (10-10) plane of a Group III nitride p-type semiconductor is not greater than 400 arcsec. Thus, the XRC FWHM of the (10-10) plane of the n-type underlying layer 3 and the n-type contact layer 4 are not greater than 400 arcsec preferably. When the (10-10) XRC FWHM is greater than 400 arcsec, the operational voltage of the light emitting device at 20 mA becomes higher and temporal changes in the forward voltage at 20 mA becomes greater, resulting in reduced reliability. Preferably growth is conducted under the condition of 350 arcsec or less, and more preferably 300 arcsec or less.

Furthermore, it was revealed by TEM examination of the section of a p-type semiconductor that when the XRC FWHM of the (10-10) plane of a Group III nitride p-type semiconductor exceeds 400 arcsec, crystals tilt and/or twist and thus the atomic array in the vicinity of the surface of the Group III nitride p-type semiconductor becomes disturbed, which may deteriorate the crystallinity of the Group III nitride p-type semiconductor. By investigating the concentration of a dopant Mg impurities by SIMS, it was confirmed that Mg has been doped at high concentrations at sites in which the atomic array was disturbed. It is estimated that this high concentration dope induced an abnormal surface condition and this aggravated crystallinity of the p-type semiconductor caused temporal changes in the forward voltage at 20 mA.

The XRC FWHM of the (10-10) plane of a Group III nitride p-type semiconductor is affected by the temperature during the growth of the Group III p-type semiconductor. In order to render the XRC FWHM 400 arcsec or less, the substrate temperature during the growth of the p-type cladding layer and the p-type contact layer is adjusted. By adjusting to the above range, the XRC FWHM of the p-type layer can be controlled to 400 arcsec or less.

Also, the Al composition of a Group III nitride p-type contact layer greatly influences the XRC FWHM of the (10-10) plane. In order to render the XRC FWHM 400 arcsec or less, the Al composition of a Group III nitride p-type contact layer is preferably 20% or less relative the total Group III elements, and more preferably 5% or less.

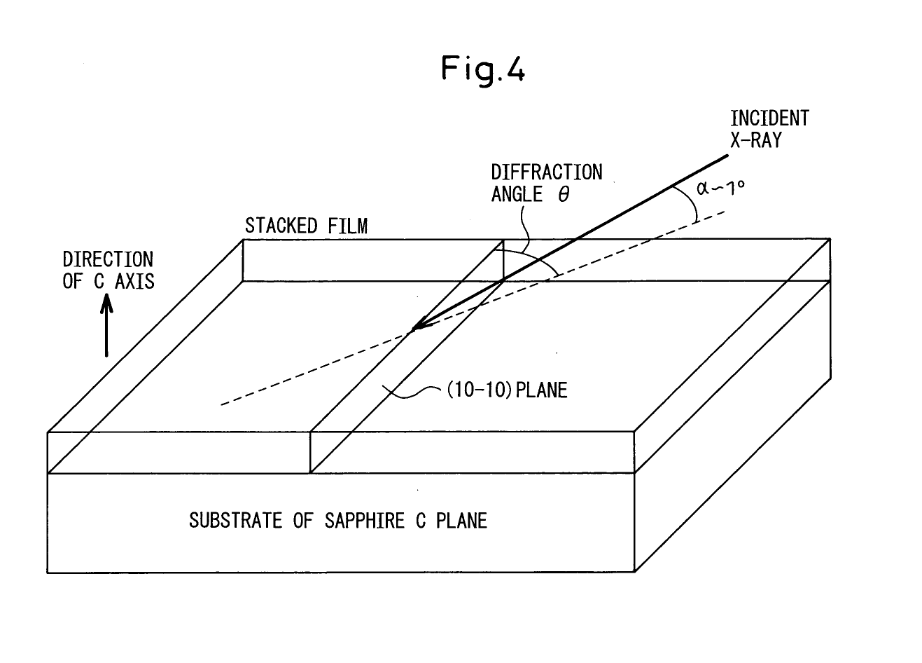

The XRC FWHM can be determined by X-ray diffraction measurement after the film forming of wafer. FIG. 4 is a schematic view explaining a method of determining a (10-10) X-ray rocking curve. When a Group III nitride semiconductor stacked structure is stacked on the sapphire C plane substrate, the (10-10) plane of a Group III nitride p-type semiconductor becomes perpendicular to the surface of the stacked film as shown in FIG. 4. When X-ray enters perfectly at a diffraction angle, the diffracted X-ray cannot not be detected. Thus, as shown in FIG. 4, by allowing X-ray to enter at an inclination angle of 1° to detect diffracted peaks, it becomes possible to determine XRC FWHM.

As materials for the positive electrode 10 that come into contact with the p-type layer formed by the method of the present invention, metals such as Au, Ni, Co, Cu, Pd, Pt, Rh, Os, Ir and Ru can be used. Transparent oxides of ITO, NiO, CoO etc., can also be used. As a form that employ a transparent oxide, they may be contained as a mass in the above metal film, or may be stacked as layers with the above metal film. A transparent oxide may be used alone. As a transparent oxide, ITO is preferred in terms of transparency and electric conductivity.

The positive electrode may be formed so as to cover the almost entire surface, or may be spaced so as to form a lattice or a treelike form. After forming the positive electrode, heat annealing may conducted for the purpose of making an alloy or achieving transparency, or may not be conducted.

As the negative electrode 20, those of various compositions and structures are known, and in the present invention as well those of any composition and structure can be used. For their production, various production methods are known and those known methods can be used.

For the fabrication of a negative electrode on the n-type contact layer, a known photolithography technology and a general etching technology can be used. By these technologies, engraving from the uppermost layer of a wafer to the n-type contact layer can be made, and the n-type contact layer in the region in which a negative electrode is to be formed can be exposed. As a material for the negative electrode, there can be used metal materials such as Cr, W and V, in addition to Al, Ti, Ni and Au as a contact metal that comes into contact with the n-type contact layer. In order to enhance intimateness with the n-type contact layer, a multilayer structure may be used in which a plurality of contact metals selected from the above are used. When Au is used on the uppermost surface, an excellent bonding property can be obtained.

Forms of light emitting devices may be the so-called face-up (FU) type in which an emitting light is extracted from the semiconductor side using a transparent positive electrode, or a flip-chip (FC) type in which an emitting light is extracted from the substrate side using a reflective positive electrode.

A Group III nitride semiconductor light emitting device formed using the production method of the present invention may be made into a lamp by mounting a transparent cover by a means known in the art. It is also possible to form a white lamp by combining a Group III nitride semiconductor light emitting device with a cover having a fluorescent body.

A lamp formed from a Group III nitride semiconductor light emitting device of the present invention has a low driving voltage and high reliability, and thus electronic appliances such as mobile phones, displays and panels that have integrated therein a lamp formed by this technology and mechanical equipment, such as automobiles, computers and game machines that have integrated therein such electronic appliances can be driven at low electric power and highly reliable, and thus can attain high characteristics. In particular, the effect of saving electric power is exhibited by battery-driven appliances such as mobile phones, game machines, toys and automobile parts.

### EXAMPLES

The present invention will now be explained in further detail with reference to examples. It should be noted, however, that the present invention is not limited to these examples in any way.

### Example 1

FIG. 2 is a schematic diagram of a section of a Group III nitride semiconductor stacked structure for semiconductor light emitting devices formed by the present example (the well layer and the barrier layer of the light emitting layer have been simplified). As shown in FIG. 2, it is a structure in which, on a sapphire substrate 1 having a C plane, a SP layer (buffer layer) 2 comprising AlN was stacked by a lattice mismatch crystal epitaxial growth technique, and thereupon, from the substrate side, a n-type underlying layer 3 comprising a 8 μm-thick undoped GaN, a n-type contact layer comprising a 2 μm-thick high Ge-doped n-type GaN having an electron concentration of about 1×10¹⁹ cm⁻³, a n-type cladding layer comprising a 20 nm-thick Ga_{0.99}In_{0.01}N having an electron concentration of about 1×10¹⁸ cm⁻³, a light emitting layer of a multiple quantum well structure in which six layers of a barrier layer comprising a 17 nm-thick Si-doped GaN having an electron concentration of about 3×10¹⁷ cm⁻³ and five layers of a well layer comprising a thin layer comprising a 3 nm-thick non-doped Ga_{0.96}In_{0.04}N have been alternately stacked, a p-type cladding layer comprising a 16 nm-thick Mg-doped p-type Al_{0.12}Ga_{0.88}N, and a p-type contact layer comprising a 220 nm-thick Mg-doped p-type Al_{0.02}Ga_{0.98}N having a positive hole concentration of 8×10¹⁷ cm⁻³ were sequentially stacked in this order.

The above Group III nitride semiconductor stacked structure was fabricated using a MOCVD method according to the following procedure.

First, the substrate of sapphire C plane was introduced into a stainless reaction furnace capable of processing multiple sheets of substrates by heating a carbon susceptor with a high frequency induction heater. The susceptor has a mechanism that allows itself to rotate and allows the substrate to rotate on its axis. The sapphire substrate was mounted on a carbon susceptor for heating in a glove box that had been gas-replaced with nitrogen. After the substrate was introduced, nitrogen gas was passed through to purge the reaction furnace.

After the nitrogen gas was passed through for eight minutes, the induction heater was operated, and thus the substrate temperature was raised to 600° C. in 10 minutes and at the same time the pressure in the furnace was set at 15 kPa. While keeping the substrate temperature at 600° C., the thermal cleaning of the substrate surface was conducted for two minutes while a hydrogen gas and a nitrogen gas were passed through.

After thermal cleaning was completed, the valve for the nitrogen gas was closed, and hydrogen alone was fed into the reaction furnace.

After switching the carrier gas, the substrate temperature was raised to 1150° C. After confirming that the temperature stabilized at 1150° C., the valve for the TMAl piping was switched to feed a gas containing TMAl steam into the reaction furnace, and then allowed to react with N atoms resulting from the decomposition of adherents that adhered on the inner wall of the reaction furnace to start the treatment of attaching AlN onto the sapphire substrate.

After treating for 11 minutes 30 seconds, the valve of the TMAl piping was switched to stop the feeding the gas containing TMAl steam into the reaction furnace. It was allowed to stand for four minutes to completely discharge the TMAl steam remaining in the furnace. Subsequently, the valve for piping ammonia gas was opened to start the feeding of ammonia gas into the furnace.

Four minutes later, while continuing the passing through of ammonia, the temperature of the susceptor was lowered to 1040° C. and the pressure in the furnace was set at 40 kPa. While lowering the susceptor temperature, the flow rate of the regulator for the TMGa piping was adjusted.

After confirming that the temperature reached 1040° C. and waiting for the temperature to stabilize, the valve of the TMGa was opened to start TMGa feeding into the furnace in order to start the growth of undoped GaN, and then the above GaN layer was allowed to grow for about four hours.

Thus, an n-type underlying layer comprising undoped GaN having a film thickness of about 8 μm was formed. The XRC FWHM of the (10-10) plane of the thus formed n-type underlying layer was 250 arcsec.

Furthermore, on this n-type underlying layer comprising undoped GaN was grown a n-type contact layer comprising a high Ge-doped n-type GaN. After the growth of a n-type underlying layer comprising undoped GaN, the feeding of the TMGa into the furnace was stopped, and then the substrate temperature was raised to 1100° C. in one minute, and maintained for three minutes in order to stabilize. In the meantime, the flow rate of tetramethyl germanium (TMGe) was adjusted. The amount to be flown had previously been investigated, and the electron concentration of the n-type contact layer comprising Ge-doped GaN was adjusted to about 2×10¹⁹ cm⁻³. The feeding of ammonia into the furnace was continued at the previous flow rate.

After temperature stabilization for three minutes, a thin film comprising a 10 nm-thick Ge-doped n-type GaN and a thin film comprising a 10 nm-thick undoped GaN were grown alternately in this order for 100 cycles to grow into a n-type contact layer comprising about 2 μm n-type GaN. Ge-doped GaN was prepared by feeding TMGa and TMGe into the furnace, and the undoped GaN layer was formed by feeding TMGa. By this, an n-type contact layer with a mean carrier concentration of about 1×10¹⁹ cm⁻³ was formed. The XRC FWHM of the (10-10) plane of the n-type GaN formed under this condition was 250 arcsec.

After growing the last undoped GaN layer, the valve of TMGa was switched to stop the feeding of TMGa into the furnace. While flowing ammonia at the previous flow rate, the valve was switched to change the carrier gas from hydrogen to nitrogen. Then, the substrate temperature was lowered from 1100° C. to 750° C.

While waiting for temperature to change in the furnace, the amount of SiH₄ fed was established. The amount to be flown had previously been investigated, and the electron concentration of the n-type cladding layer comprising Si-doped GaInN was adjusted to 1×10¹⁸ cm⁻³. The feeding of ammonia into the furnace was continued at the previous flow rate.

While waiting for the state in the furnace to stabilize, the valves for the TMIn, TEGa and SiH₄ were set to open at the same time to start the feeding of these materials into the furnace. By continuing the feeding for a predetermined time, an n-type cladding layer comprising Si-doped Ga_{0.99}In_{0.01}N having a film thickness of 20 nm was formed.

After forming an n-type cladding layer comprising Si-doped Ga_{0.99}In_{0.01}N, the valves for TMIn, TEGa and SiH₄ were switched to stop the feeding of these materials. After stopping the feeding of materials, the setting of the amount of SiH₄ fed was changed. The amount to be flown had previously been investigated, and the electron concentration of a barrier layer comprising Si-doped GaN was adjusted to 3×10¹⁷ cm⁻³. The barrier layer comprising Si-doped GaN was formed as described below.

While keeping the substrate temperature at 750° C., the feeding of TEGa and SiH₄ into the furnace was started to form a thin barrier layer A comprising Si-doped GaN for a predetermined time, and the feeding of TEGa and SiH₄ was stopped. Then, while suspending the growth, the temperature was raised to 900° C. After the temperature stabilized, the valves for the TEGa and SiH₄ were switched to resume the feeding of TEGa and SiH₄ into the furnace while maintaining the substrate temperature, pressure in the furnace, and the flow rate of the ammonia gas and carrier gas, and as a result barrier layer B was grown at a substrate temperature of 900° C. for a predetermined time. After the growth of barrier layer B, the feeding of TEGa and SiH₄ into the furnace was stopped. Subsequently, the susceptor temperature was lowered to 750° C., and the feeding of TEGa and SiH₄ was started to grow barrier layer C. Then, the valve was switched to stop the feeding of TEGa and SiH₄ and the growth of the GaN barrier layer was completed, and as a result a three-layered barrier layer comprising A, B and C, or a Si-doped GaN barrier layer with a total film thickness of 17 nm was formed.

After the completion of the growth of a barrier layer comprising GaN, the feeding of TEGa and SiH₄ was suspended for 30 seconds, and after the setting of the amount fed of TEGa was changed to a flow rate that had previously been investigated, the valves for the TEGa and TMIn were switched to feed TEGa and TMIn into the furnace while keeping the substrate temperature, pressure in the furnace, and the flow rate of the ammonia gas and the carrier gas as they are, and the well layer was formed. After feeding TEGa and TMIn for a predetermined time, the valves were switched again to stop the feeding of TEGa and TMIn to complete the growth of a well layer comprising Ga_{0.96}In_{0.04}N. At this time point, a Ga_{0.96}In_{0.04}N layer having a film thickness of 4 nm was formed. After the growth of the Ga_{0.96}In_{0.04}N well layer, the setting of the amount fed of TEGa was changed. Subsequently, the feeding of TEGA and SiH₄ was resumed to start the forming of a second barrier layer.

By repeating the procedure as above five times, five Si-doped GaN barrier layers and five Ga_{0.92}In_{0.04}N well layers were formed. In the process of forming these well layers and barrier layers, after forming barrier layer A at 750° C., the growth of the semiconductor layer was suspended by stopping the feeding of Group III materials when the temperature was raised to 900° C. for forming a barrier layer B.

After forming a fifth Ga_{0.96}In_{0.04}N well layer, the forming of a sixth barrier layer was started. In the forming of the sixth barrier layer, the feeding of SiH₄ was resumed to form a barrier layer A comprising Si-doped GaN, and then the substrate temperature was raised to 900° C. while maintaining the feeding of TEGa and SiH₄ into the furnace, and barrier layer B was grown for a predetermined time at a temperature of 900° C. After the growth of barrier layer B, the feeding of TEGa and SiH₄ into the furnace was stopped, the substrate temperature was lowered to 750° C., and the feeding of TEGa and SiH₄ was started to grow barrier layer C, and then the valves were switched again to stop the feeding of TEGa and SiH₄ to complete the growth of the GaN barrier layer. This resulted in the formation of a three-layered barrier layer comprising A, B and C, which was a 17 nm-thick Si-doped GaN barrier layer.

According to the above procedure, a light emitting layer of a multiple quantum well structure comprising well layers (layers 1 to 4) having an uneven thickness and a well layer (layer 5) having an even thickness was formed.

On the light emitting layer that ends with this Si-doped GaN barrier layer, a p-type cladding layer comprising a Mg-doped p-type Al_{0.12}Ga_{0.88}N was formed.

After completing the growth of the Si-doped GaN barrier layer by stopping the feeding of TEGa and SiH₄, the substrate temperature was raised to 1000° C., the carrier gas type was changed to hydrogen, and the pressure in the furnace was changed to 15 kPa. After the pressure in the furnace stabilized, the valves for the TMGa, TMAl and Cp₂Mg were switched, and then fed into the furnace. Subsequently, after growing for about three minutes, the feeding of TEGa and TMAl was stopped to stop the growth of a p-type cladding layer comprising a Mg-doped p-type Al_{0.12}Ga_{0.88}N. This resulted in a formation of a p-type cladding layer comprising a Mg-doped p-type Al_{0.12}Ga_{0.88}N having a film thickness of 16 nm.

On the Mg-doped p-type Al_{0.12}Ga_{0.88}N cladding layer, a p-type contact layer was formed comprising a Mg-doped p-type Al_{0.02}Ga_{0.98}N.

After completing the growth of the Mg-doped p-type Al_{0.12}Ga_{0.88}N cladding layer by stopping the feeding of TMGa, TMAl and Cp₂Mg, the substrate temperature was lowered to 990° C., and the amount of TMGa, TMAl and CP₂Mg fed was changed while maintaining the carrier gas and pressure in the furnace. Subsequently, while continuing the feeding of ammonia gas into the furnace, the valves for the TMGa, TMAl and cp₂Mg were switched, and the feeding of these materials into the furnace was started. The amount of Cp₂Mg to be flown had previously been investigated, and the positive hole concentration of the Mg-doped p-type Al_{0.02}Ga_{0.98}N contact layer was adjusted to 8×10¹⁷ cm⁻³.

After changing the feed amount, a first p-type contact layer was grown by 70 nm at a substrate temperature of 990° C. for about 3 minutes 30 seconds, and by raising the substrate temperature from 990° C. to 1040° C. for about three minutes while continuing the feeding of TMGa, TMAl, Cp₂Mg and NH₃, it was grown by 60 nm, and then a second p-type contact layer was grown by 90 nm at 1040° C. for 4 minutes 30 seconds. After completion of the growth, the feeding of TMGa, TMAl and Cp₂Mg was stopped to stop the growth of a Mg-doped p-type Al_{0.02}Ga_{0.98}N contact layer. This resulted in the formation of a Mg-doped p-type Al_{0.02}Ga_{0.98}N contact layer having a total film thickness of about 220 nm. X-ray diffraction confirmed that in this range of temperature rise, the Al composition of the p-type AlGaN contact layer does not change.

After stopping the growth of the gas phase of the Mg-doped p-type Al_{0.02}Ga_{0.98}N contact layer, the passing of current to the high frequency induction heater that had been used for heating the substrate was immediately stopped. At the same time, the carrier gas was switched from hydrogen to nitrogen and the flow rate of ammonia was lowered. Specifically the volume of ammonia gas that accounted for about 14% of the total gas flow during growth was lowered to 0.2%.

Furthermore, after keeping this state for 45 seconds, the flow of ammonia was stopped. In this state, by confirming the reduction of the substrate temperature to room temperature, the formed Group III nitride semiconductor stacked structure was taken out and placed into a room atmosphere.

By the above procedure, a Group III nitride semiconductor stacked structure for a semiconductor light emitting device was formed. The Mg-doped p-type Al_{0.02}Ga_{0.98}N contact layer exhibited a p-type without an annealing treatment for activating p-type carriers.

The X-ray rocking curve (XRC) of the diffraction plane of the (10-10) plane of the Group III nitride semiconductor stacked structure obtained was determined to analyze the FWHM of the diffraction peak. The XRC FWHM of the (10-10) plane was good at 298 arcsec. Under TEM examination, no dislocations in the atomic lattice image were observed in the vicinity of the p-type layer surface, and it was found to be a p-type layer having good crystallinity.

Then, a light emitting diode, a kind of semiconductor light emitting device, was fabricated using the above Group III nitride semiconductor stacked structure.

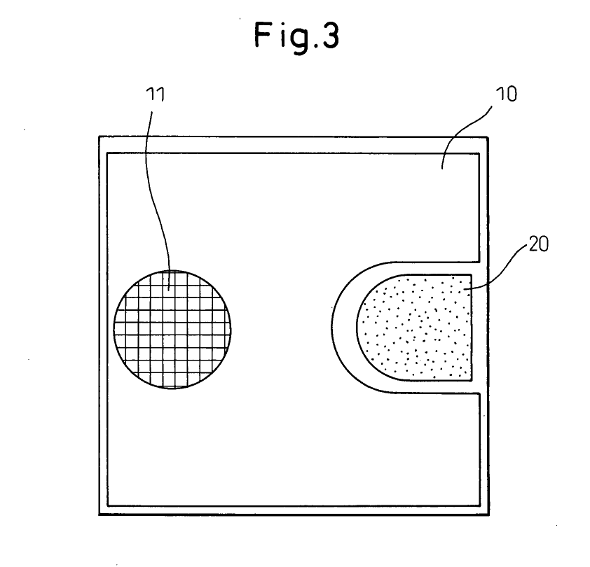

An LED was fabricated using the formed Group III nitride semiconductor stacked structure. First, general dry etching was done in a region in which a negative electrode (n-type ohmic electrode) 20 was to be formed, and on the region alone, the surface of a Ge-doped GaN layer was exposed. On the exposed surface portion, a n-type ohmic electrode 20, in which titanium (Ti)/aluminum (Al) (titanium is on the semiconductor side) were layered, was formed. On almost the entire region of the surface of the p-type contact layer, a 350 nm-thick positive electrode (p-type ohmic electrode) 10 comprising ITO was formed. Furthermore, a positive bonding pad 11 was formed in which Ti, Au, Al and Au were stacked in this order on the p-type ohmic electrode (Ti is on the ohmic electrode side). By these procedures, an electrode having a shape as shown in FIG. 3 was formed.

For the Group III nitride semiconductor stacked structure in which a positive electrode and a negative electrode were thus formed, the back surface of the sapphire substrate was abraded and polished to create a mirror-like surface. Subsequently, the Group III nitride semiconductor stacked structure was cut into 350 μm-square chips. Furthermore, the chips were mounted on a lead frame, and connected to the lead frame via metal wires to make a light emitting diode.

When a forward electric current was applied between the positive electrode and the negative electrode of the light emitting diode thus formed, a forward voltage (driving voltage) with an electric current of 20 mA was 3.33 V. The light emitting wavelength was 405 nm and the light emitting output at an applied current of 20 mA was 13.5 mW. The characteristics of such a light emitting diode was evenly obtained for light emitting diodes formed on almost the entire surface of the formed Group III nitride semiconductor stacked structure.

When an aging test was conducted in which a current of 30 mA was applied in a forward direction to this light emitting diode, and forward voltage at an electric current of 20 mA at the start and 100 hours later were measured, and the rate of change in the forward voltage with an electric current of 20 mA at the start and 100 hours later were compared, the rate of change in voltage was good at −0.5% (a minus in the rate of change means a reduction in voltage after aging). Also, the rate of change in a forward voltage at a low current band of 10 μA was −1.4%, and though a rise in temperature in one step may expand the rate of change, a rise in temperature in two steps was able to suppress the variation in the rate of change, and the leakage of current in the low current band did not grow.

Growth parameters of Example 1 are summarized below:

n-type underlying layer: substrate temperature T=1040° C.

p-type cladding layer: substrate temperature T0=1000° C., film thickness=16 nm

First stage p-type contact layer: substrate temperature T1=990° C., film thickness t1=70 nm

Second stage p-type contact layer: substrate temperature T2=1040° C., film thickness t2=90 nm

The film thickness of a p-type contact layer grown while raising the temperature of the first stage p-type contact layer to the temperature of second stage p-type contact layer: 60 nm.

### Comparative Example 1

### Low-Temperature Constant Growth of a p-Type Contact Layer

A Group III nitride semiconductor stacked structure and a light emitting diode were fabricated in the same manner as in Example 1, except that the substrate temperature for growing the p-type contact layer was set at a constant of 990° C., and the light emitting diode obtained was evaluated in the same manner as in Example 1.

In Comparative Example 1, a forward voltage (VF) at 20 mA increased to 3.65 V. The rate of change of driving voltage due to aging was as high as −2.8% and the light emitting output of the LED was as low as 9.3 mW. The XRC FWHM of the (10-10) plane of the p-type semiconductor layer was undesirable at 450 arcsec. The wafer surface after the growth of the p-type semiconductor layer was rugged, and under TEM examination, dislocations in the atomic lattice image in the vicinity of the surface of the p-type contact layer were observed, indicating that the p-type layer had an undesirable crystallinity.

### Comparative Example 2

### High-Temperature Constant Growth of a p-Type Contact Layer

A Group III nitride semiconductor stacked structure and a light emitting diode were fabricated in the same manner as in Example 1, except that the substrate temperature for growing the p-type contact layer was set at a constant of 1040° C., and the light emitting diode obtained was evaluated in the same manner as in Example 1.

In Comparative Example 2, a forward voltage at 20 mA was low at 3.53 V compared to Example 1, whereas the output was low at 9.8 mW. Furthermore, the rate of change of the forward voltage in the low-current band at 10 μA was −4.4%, and the leak components in the low-current band increased. Under TEM examination, In segregation which is considered to be thermal damage in the light emitting layer was confirmed. The XRC FWHM of the (10-10) plane was 416 arcsec, and it is thought that the deteriorated crystallinity of the light emitting layer aggravated the crystallinity of the p-type layer.

### Examples 2-6

### Temperature Dependence of the Growth of the p-Type Contact Layer in the Second Stage

A Group III nitride semiconductor stacked structure and a light emitting diode were fabricated in the same manner as in Example 1, except that the substrate temperature for growing the p-type contact layer in the second stage was variously changed, and the light emitting diode obtained was evaluated in the same manner as in Example 1. The temperature conditions for growth of each semiconductor layer and the results of evaluation are shown in Table 1. The results of Example 1 and Comparative Examples 1 and 2 are also shown in Table 1.

Due to a rise in substrate temperature in the second stage, a forward voltage at 20 mA decreased, voltage variation due to aging was suppressed, and the light emitting output increased. The FWHM of the XRC (10-10) plane became smaller, and the crystallinity of the p-type layer was improved due to the temperature rise.

As shown in Example 6, however, a rise in temperature of up to 1070° C. led to a slight reduction in output and the rate of change in forward voltage in the low current band of 10 HA became greater. Also the XRC FWHM of the (10-10) plane of the p-type semiconductor layer became slightly greater, and thermal damage to the light emitting layer led to reduced crystallinity of the p-type layer.

By raising the substrate temperature during the growth of the p-type contact layer in two stages, voltage during operation at 20 mA decreased without lowering the light emitting output, and voltage variation due to aging was suppressed, and therefore the reliability of the fabricated light emitting diode could be enhanced.

TABLE 1

| | n | p | | | | VF10uA | VF20mA | | Light |
|---|---|---|---|---|---|---|---|---|---|
| | Underlying | cladding | p contact | p contact | | rate of | rate of | XRC | emitting |
| | layer | layer | layer | layer | VF20mA | change | change | (10-10) | output |
| | T[° C.] | T0[° C.] | T1[° C.] | T2[° C.] | [V] | [%] | [%] | [arcsec] | [mW] |
| Example 1 | 1040 | 1000 | 990 | 1040 | 3.33 | −1.4 | −0.5 | 298 | 13.5 |
| Example 2 | 1040 | 1000 | 990 | 1020 | 3.53 | −1.4 | −1.1 | 360 | 12.5 |
| Example 3 | 1040 | 1000 | 990 | 1030 | 3.44 | −1.4 | −0.8 | 335 | 12.6 |
| Example 4 | 1040 | 1000 | 990 | 1050 | 3.30 | −1.4 | −0.5 | 290 | 13.3 |
| Example 5 | 1040 | 1000 | 990 | 1060 | 3.30 | −1.3 | −0.4 | 295 | 12.8 |
| Example 6 | 1040 | 1000 | 990 | 1070 | 3.32 | −3.4 | −0.4 | 330 | 10.8 |
| Comparative | 1040 | 1000 | 990 | 990 | 3.65 | −1.4 | −2.8 | 450 | 9.3 |
| Example 1 | | | | | | | | | |
| Comparative | 1040 | 1000 | 1040 | 1040 | 3.53 | −4.4 | −1.1 | 416 | 9.8 |
| Example 2 | | | | | | | | | |

The light emitting device obtained using a Group III nitride semiconductor stacked structure produced by the production method of the present invention has a high light emitting output and a low forward voltage (driving voltage) at 20 mA, and further has a small temporal rate of change in forward voltage at 20 mA and has a high reliability. Thus, it has a tremendous industrial usefulness as, for example lamps, etc.

What is claimed is:

1. A method of producing a Group III nitride semiconductor stacked structure having a n-type underlying layer, an active layer, a p-type cladding layer and a p-type contact layer, each comprising a Group III nitride semiconductor, in this order on a substrate, wherein the p-type contact layer is grown at two or more times the temperature range of the substrate temperature, and the temperature range at the later growth is higher than that at the first growth.

2. A method of producing a Group III nitride semiconductor stacked structure according to claim 1, wherein the active layer comprises In.

3. A method of producing a Group III nitride semiconductor stacked structure according to claim 1, wherein the p-type cladding layer comprises aluminum gallium nitride (AlₓGa₁₋ₓN: 0≦x≦0.5).

4. A method of producing a Group III nitride semiconductor stacked structure according to claim 1, wherein the p-type contact layer comprises aluminum gallium nitride (AlₓGa₁₋ₓN: 0≦x≦0.1).

5. A method of producing a Group III nitride semiconductor stacked structure according to claim 1, wherein when the substrate temperature during the growth of the n-type underlying layer is set at T0° C., the substrate temperature during the growth of the p-type cladding layer is set at T0° C., the substrate temperature in first stage during the growth of the p-type contact layer is set at T1° C., and the substrate temperature in the second stage during the growth of the p-type contact layer is set at T2° C., T, T0, T1 and T2 satisfy the following formula:
T−70<T1<T
T−30<T2<T+30
T1<T2
T0<T, T2

6. A Group III nitride semiconductor stacked structure produced by the method according to claim 1.

7. A Group III nitride semiconductor stacked structure having a n-type underlying layer, an active layer, a p-type cladding layer and a p-type contact layer, each comprising a Group III nitride semiconductor, in this order on a substrate wherein the half-width of an X-ray rocking curve (XRC FWHM) of the (10-10) plane of the p-type contact layer is 400 arcsec or smaller.

8. A Group III nitride semiconductor stacked structure according to claim 6, wherein the thickness of the p-type contact layer is 50-300 nm.

9. A Group III nitride semiconductor stacked structure according to claim 8, wherein the thickness of the p-type contact layer in the first stage is 10 nm or greater.

10. A Group III nitride semiconductor stacked structure according to claim 8, wherein the thickness of the p-type contact layer in the second stage is 30 nm or greater.

11. A Group III nitride semiconductor stacked structure according to claim 6, wherein the thickness of the p-type cladding layer is 10-100 nm.

12. A light emitting device comprising a Group III nitride semiconductor stacked structure according to claim 6.

13. A light emitting device according to claim 12, wherein the light emitting wavelength is 420 nm or smaller.

14. A lamp comprising a light emitting device according to claim 12.

15. An electronic device in which the lamp according to claim 14 has been integrated.

16. A mechanical instrument in which the electronic device according to claim 15 has been integrated.
